(19) United States
(12) Patent Application Publication
(10) Pub. No.: US 2026/0080924 A1
(43) Pub. Date: Mar. 19, 2026

(54) STORAGE DEVICE

(71) Applicant: Kioxia Corporation, Tokyo (JP)

(72) Inventor: Masahiko NAKAYAMA, Yokohama Kanagawa (JP)

(21) Appl. No.: 19/076,932

(22) Filed: Mar. 11, 2025

(30) Foreign Application Priority Data
Sep. 17, 2024 (JP) 2024-160318

(51) Int. Cl. G11C 11/16

(52) U.S. Cl. CPC G11C 11/1693; G11C 11/1673; G11C 11/1697

(57) ABSTRACT

According to embodiments, a storage device includes a memory cell connected between first and second wires, the memory cell including a variable resistance memory element and a switching element, and the storage device further includes a controller configured to: set the switching element to an ON state at a first time point, and obtain a voltage to be determined applied between the first and second wires when a first time period elapses; set the variable resistance memory element to a reference resistance state during a write period; set the switching element to the ON state at a second time point, and obtain a reference voltage applied between the first and second wires when a second time period different from the first time period elapses; and determine, based on the voltage to be determined and the reference voltage, a resistance state to be determined of the variable resistance memory element.

### CROSS-REFERENCE TO RELATED APPLICATION

This application is based upon and claims the benefit of priority from Japanese Patent Application No. 2024-160318, filed Sep. 17, 2024, the entire contents of which are incorporated herein by reference.

### FIELD

Embodiments described herein relate generally to a storage device.

### BACKGROUND

A storage device has been proposed in which a plurality of memory cells, each of which includes a variable resistance memory element and a switching element such as a selector, are integrated on a semiconductor substrate.

### BRIEF DESCRIPTION OF THE DRAWINGS

FIG. 1 is a diagram illustrating a general configuration of a storage device according to embodiments.

FIG. 2 is a perspective view schematically illustrating a basic configuration of a memory cell array region of the storage device according to embodiments.

FIG. 3 is a cross-sectional view schematically illustrating a basic configuration of a magnetoresistance effect element of the storage device according to embodiments.

FIG. 4 is a cross-sectional view schematically illustrating a basic configuration of a selector of the storage device according to embodiments.

FIG. 5 is a diagram schematically illustrating current-voltage characteristics of the selector of the storage device according to embodiments.

FIG. 6 is a diagram schematically illustrating current-voltage characteristics at the time of reading of memory cells of the storage device according to embodiments.

FIG. 7 is a timing chart illustrating a basic operation of self-reference reading of the storage device according to embodiments.

FIG. 8 is a flowchart illustrating the basic operation of self-reference reading of the storage device according to embodiments.

FIG. 9 is a diagram illustrating a first example of the determination operation of the storage device according to embodiments.

FIG. 10 is a diagram illustrating a second example of the determination operation of the storage device according to embodiments.

FIG. 11 is a diagram illustrating a time measuring unit of the storage device according to embodiments.

### DETAILED DESCRIPTION

A storage device capable of accurately reading data stored in memory cells is provided.

In general, according to embodiments, a storage device includes a first wire extending in a first direction; a second wire extending in a second direction that intersects the first direction; and a memory cell connected between the first wire and the second wire. The memory cell includes a variable resistance memory element capable of exhibiting both a first resistance state and a second resistance state having a greater resistance than the first resistance state, and the memory cell further includes a switching element connected in series to the variable resistance memory element, the switching element having characteristics of transitioning from an OFF state to an ON state when a voltage applied between two terminals of the switching element increases to a first voltage, and of transitioning from the ON state to the OFF state when the voltage applied between the two terminals decreases to a second voltage lower than the first voltage. The storage device further includes a determination operation controller configured to: change a voltage of the first wire at a first ON state setting time point during a first read period, to set the switching element to the ON state while the second wire is set to a floating state, and obtain a voltage to be determined that is applied between the first wire and the second wire when a first time period elapses since the first ON state setting time point; set the variable resistance memory element to one of the first resistance state and the second resistance state as a reference resistance state during a write period after the first read period; change the voltage of the first wire at a second ON state setting time point during a second read period after the write period, to set the switching element to the ON state while the second wire is set to the floating state, and obtain a reference voltage applied between the first wire and the second wire when a second time period, which is different from the first time period, elapses since the second ON state setting time point; and determine, based on a voltage difference between the voltage to be determined and the reference voltage, a resistance state to be determined that the variable resistance memory element was set to before the first read period.

Hereinafter, embodiments will be described with reference to the drawings.

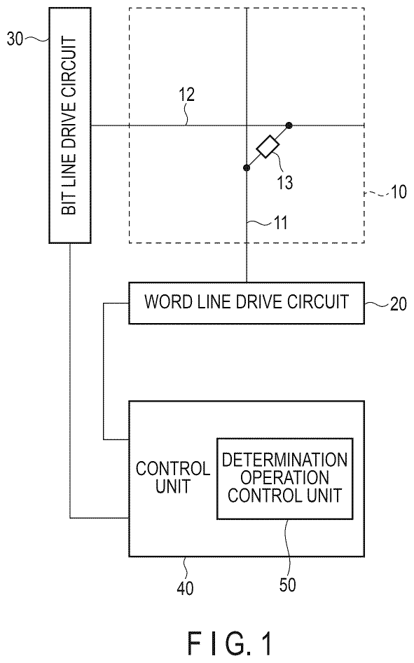

FIG. 1 is a diagram illustrating a general configuration of a storage device according to embodiments.

The storage device illustrated in FIG. 1 includes a memory cell array region 10, a word line drive circuit 20, a bit line drive circuit 30, and a control unit 40, also referred to herein as a “controller.”

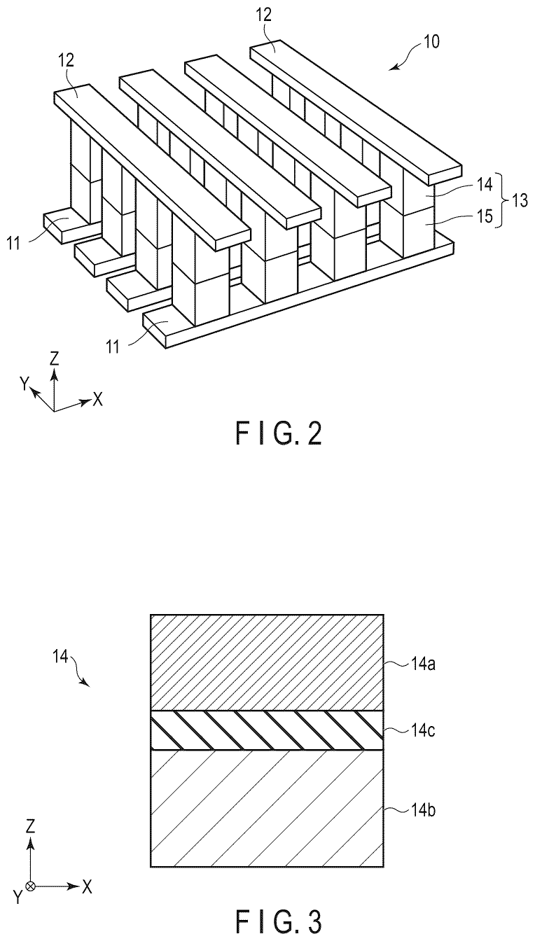

FIG. 2 is a perspective view schematically illustrating a basic configuration of the memory cell array region 10 described above.

As illustrated in FIG. 2, in the memory cell array region 10, there are provided a plurality of word lines 11 each extending in an X direction, a plurality of bit lines 12 each extending in a Y direction, and a plurality of memory cells 13 connected between the plurality of word lines 11 and the plurality of bit lines 12. It is possible to perform writing to and reading from a selected memory cell 13 by applying a predetermined current between a selected word line 11 connected to the selected memory cell 13 and a selected bit line 12 connected to the selected memory cell 13.

Each memory cell 13 includes a variable resistance memory element such as a magnetoresistance effect element 14 that is capable of exhibiting both a low resistance state and a high resistance state having a greater resistance than the low resistance state, and a two-terminal switching element such as a selector 15 that is connected in series to the magnetoresistance effect element 14. The magnetoresistance effect element 14 and the selector 15 are stacked in a Z direction.

The X direction, the Y direction, and the Z direction are directions that intersect with each other. Specifically, the X direction, the Y direction, and the Z direction are perpendicular to each other.

Note that, in the example illustrated in FIG. 2, although the magnetoresistance effect element 14 is provided on an upper layer side of the selector 15, the magnetoresistance effect element 14 may be provided on a lower layer side of the selector 15. In addition, in the example illustrated in FIG. 2, although the bit lines 12 are provided on an upper layer side of the word lines 11, the bit lines 12 may be provided on a lower layer side of the word lines 11.

FIG. 3 is a cross-sectional view schematically illustrating a basic configuration of the magnetoresistance effect element 14. The magnetoresistance effect element 14 is a non-volatile variable resistance memory element, and is an MTJ (magnetic tunnel junction) element.

As illustrated in FIG. 3, the magnetoresistance effect element 14 includes a storage layer 14a, a reference layer 14b, and a tunnel barrier layer 14c, the storage layer 14a and the reference layer 14b both being magnetic, and the tunnel barrier layer 14c being non-magnetic.

The storage layer 14a is a ferromagnetic layer with a variable magnetization direction. The reference layer 14b is a ferromagnetic layer with a fixed magnetization direction. The tunnel barrier layer 14c is an insulating layer provided between the storage layer 14a and the reference layer 14b. Note that having a variable magnetization direction means that the magnetization direction changes for a predetermined write current. Having a fixed magnetization direction means that the magnetization direction does not change for the predetermined write current.

When the magnetization direction of the storage layer 14a is parallel to the magnetization direction of the reference layer 14b, the magnetoresistance effect element 14 exhibits the low resistance state. When the magnetization direction of the storage layer 14a is antiparallel to the magnetization direction of the reference layer 14b, the magnetoresistance effect element 14 exhibits the high resistance state. The magnetoresistance effect element 14 can store binary data according to the resistance state. In addition, the resistance state of the magnetoresistance effect element 14 can be set according to the direction of a write current flowing through the magnetoresistance effect element 14.

Note that, although the example illustrated in FIG. 3 is a top-free type magnetoresistance effect element in which the storage layer 14a is located above the reference layer 14b in the Z direction, a bottom-free type magnetoresistance effect element in which the storage layer 14a is located below the reference layer 14b may be used.

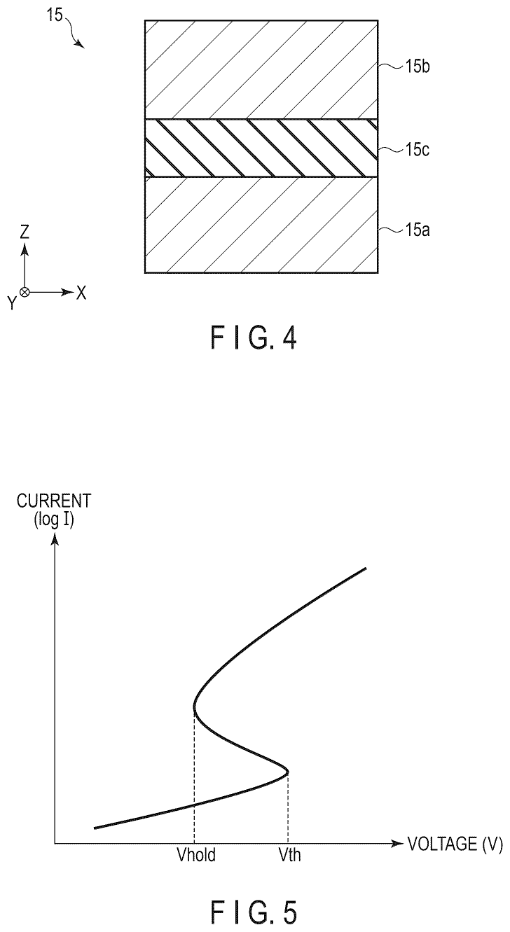

FIG. 4 is a cross-sectional view schematically illustrating a basic configuration of the selector 15.

As illustrated in FIG. 4, the selector 15 includes a lower electrode 15a, an upper electrode 15b, and a switching material layer such as a selector material layer 15c provided between the lower electrode 15a and the upper electrode 15b for switching. The selector material layer 15c may be formed of, for example, silicon oxide containing a predetermined element such as arsenic (As).

FIG. 5 is a diagram schematically illustrating current-voltage characteristics of the selector 15.

As illustrated in FIG. 5, the selector 15 has characteristics such that when the voltage applied between the two terminals of the selector 15 (i.e., between the lower electrode 15a and the upper electrode 15b) increases to a threshold voltage Vth, the selector 15 transitions from an OFF state to an ON state, and when the voltage applied between the two terminals decreases from the threshold voltage Vth to a hold voltage Vhold lower than the threshold voltage Vth, the selector 15 transitions from the ON state to the OFF state.

By applying a voltage between the word line 11 and the bit line 12 to turn ON the selector 15, a current flows through the magnetoresistance effect element 14 connected in series to the selector 15, and it becomes possible to perform writing to and reading from the magnetoresistance effect element 14.

Let us return to the description of FIG. 1. The word line drive circuit 20 selects and drives the word line 11 connected to the selected memory cell 13, and the bit line drive circuit 30 selects and drives the bit line 12 connected to the selected memory cell 13. By applying a voltage between the selected word line 11 and the selected bit line 12 to apply the predetermined current through the selected memory cell 13, it becomes possible to perform writing to and reading from the selected memory cell 13 as described above.

The control unit 40 is a circuit that performs various kinds of control including control of the word line drive circuit 20 and the bit line drive circuit 30, and includes a determination operation control unit 50, also referred to herein as a “determination operation controller. ” The determination operation control unit 50 is a sub-circuit of the control unit 40 that controls a determination operation of the resistance state of the magnetoresistance effect element 14 included in the selected memory cell 13. That is, the determination operation control unit 50 controls the determination operation to determine the resistance state to be determined as either the low resistance state or the high resistance state, and the determined resistance state is applied in advance to the magnetoresistance effect element 14. Based on the resistance state to be determined, the binary data that is stored in advance in the magnetoresistance effect element 14 is determined.

Next, a self-reference reading operation of embodiments will be described.

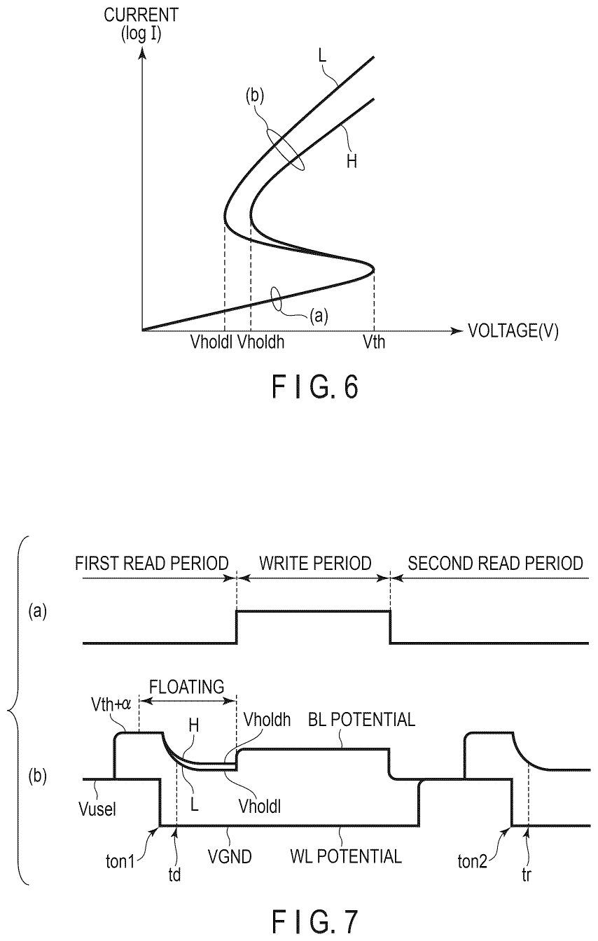

FIG. 6 is a diagram schematically illustrating current-voltage characteristics at the time of reading of the selected memory cell 13. In FIG. 6, a horizontal axis represents the voltage applied across both ends of the selected memory cell 13, which is approximately equal to the voltage applied between the selected word line 11 and the selected bit line 12. A vertical axis represents the current flowing through the selected memory cell 13, which is approximately equal to the current flowing between the selected word line 11 and the selected bit line 12. In addition, characteristics L are the characteristics in a case where the magnetoresistance effect element 14 is set to the low resistance state. Characteristics H are characteristics in a case where the magnetoresistance effect element 14 is set to the high resistance state.

Note that, hereinafter, unless otherwise specified, the description will be given with respect to the selected word line 11, the selected bit line 12, and the selected memory cell 13, and the selected word line 11, the selected bit line 12, and the selected memory cell 13 will be referred to simply as “the word line 11,”“the bit line 12,”and “the memory cell 13,”respectively.

Generally, the resistance of the selector 15 in the OFF state is sufficiently greater than the resistance of the magnetoresistance effect element 14, including both the resistance of the magnetoresistance effect element 14 when in the low resistance state and the resistance thereof when in the high resistance state. Therefore, the current-voltage characteristics of the memory cell 13 at a characteristic portion (a) are the same in the case where the magnetoresistance effect element 14 is set to the low resistance state, as they are in the case where the magnetoresistance effect element 14 is set to the high resistance state, until the selector 15 transitions from the OFF state to the ON state. That is, the threshold voltage Vth applied across both ends of the memory cell 13 when the selector 15 transitions from the OFF state to the ON state is substantially the same in the case where the magnetoresistance effect element 14 is set to the low resistance state, as it is in the case where the magnetoresistance effect element 14 is set to the high resistance state.

On the other hand, generally, although the resistance of the selector 15 in the ON state is lower than the resistance of the magnetoresistance effect element 14, including both the resistance of the magnetoresistance effect element 14 when in the low resistance state and the resistance thereof when in the high resistance state, the resistance of the selector 15 in the ON state is no longer sufficiently lower than the resistance of the magnetoresistance effect element 14. Therefore, after the selector 15 transitions from the OFF state to the ON state, a difference occurs in the current-voltage characteristics of the memory cell 13 at a characteristic portion (b) between the case where the magnetoresistance effect element 14 is in the low resistance state and the case where the magnetoresistance effect element 14 is in the high resistance state.

The voltage applied across both ends of the memory cell 13 when the selector 15 transitions from the ON state to the OFF state is Vholdl when the magnetoresistance effect element 14 is in the low resistance state, and is Vholdh when the magnetoresistance effect element 14 is in the high resistance state. Therefore, when a read current is supplied to the memory cell 13, a difference occurs in the voltage across both ends of the memory cell 13 between the case where the magnetoresistance effect element 14 is in the low resistance state, and the case where the magnetoresistance effect element 14 is in the high resistance state. Accordingly, it is possible to determine the resistance state of the magnetoresistance effect element 14 as either the low resistance state or the high resistance state based on such a difference in the voltage.

FIG. 7 is a timing chart illustrating the self-reference reading operation of embodiments.

The part (a) of FIG. 7 illustrates the timings of a first read period, a write period, and a second read period, which will be described later. The part (b) of FIG. 7 illustrates the electric potential of the word line 11 and the electric potential of the bit line 12. L is the electric potential of the bit line 12 in the case where the magnetoresistance effect element 14 is set to the low resistance state as the resistance state to be determined, and H is the electric potential of the bit line 12 in the case where the magnetoresistance effect element 14 is set to the high resistance state as the resistance state to be determined.

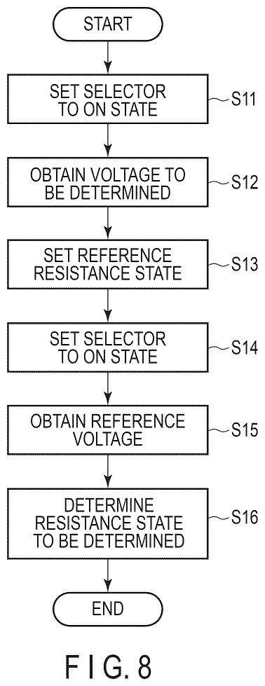

FIG. 8 is a flowchart illustrating the basic operation of self-reference reading.

Hereinafter, referring to FIG. 7 and FIG. 8, the self-reference reading operation will be described. Note that the following operation is mainly performed under the control of the determination operation control unit 50.

First, the same voltage Vusel is applied to the word line 11 and the bit line 12. The value of the voltage Vusel is approximately half of the value of the threshold voltage Vth described above. At this time, the voltage applied to the memory cell 13 is zero.

Next, a voltage (Vth+α) slightly greater than the threshold voltage Vth is applied to the bit line 12. The voltage Vusel is still applied to the word line 11.

Next, the bit line 12 is set to a floating state. At this time, the voltage of the bit line 12 is maintained at (Vth+α).

Next, as the bit line 12 is maintained in the floating state, the voltage of the word line 11 is changed to apply a ground voltage VGND to the word line 11. Accordingly, the voltage (Vth+α), which is greater than the threshold voltage Vth, is applied between the word line 11 and the bit line 12. As a result, the voltage (Vth+α) is applied to the memory cell 13, and the selector 15 in the memory cell 13 transitions from the OFF state to the ON state. That is, the selector 15 is set to the ON state at a first ON state setting time point ton1 at which the voltage of the word line 11 is changed to apply the ground voltage VGND to the word line 11 (S11).

When the selector 15 transitions from the OFF state to the ON state, a current flows between the word line 11 and the bit line 12 via the memory cell 13. At this time, since the bit line 12 is maintained in the floating state, the electric potential of the bit line 12 automatically gradually decreases as the current flows.

When the electric potential of the bit line 12 decreases, and the voltage between the word line 11 and the bit line 12 becomes the hold voltage Vhold (Vholdl or Vholdh illustrated in FIG. 6), the voltage across both ends of the memory cell 13 becomes the hold voltage Vhold, and the selector 15 transitions from the ON state to the OFF state.

As already described, after the selector 15 transitions from the OFF state to the ON state, the voltage across both ends of the memory cell 13 is different in the case where the magnetoresistance effect element 14 is in the low resistance state than it is in the case where the magnetoresistance effect element 14 is in the high resistance state. That is, the voltage between the word line 11 and the bit line 12 is different in the case where the magnetoresistance effect element 14 is in the low resistance state than it is in the case where the magnetoresistance effect element 14 is in the high resistance state. Therefore, while the bit line 12 is in the floating state, at a voltage to be determined obtaining time point td, which occurs after a first time period elapses since the first ON state setting time point ton1, a voltage applied between the word line 11 and the bit line 12 is obtained as the voltage to be determined (S12). The voltage to be determined obtaining time point td occurs before the selector 15 transitions from the ON state to the OFF state.

In this manner, after the voltage to be determined is obtained during the first read period, an operation in the write period is performed. In the write period, the magnetoresistance effect element 14 is set to one of the low resistance state and the high resistance state as a reference resistance state (S13). Specifically, the magnetoresistance effect element 14 is set to the reference resistance state by applying a predetermined voltage between the word line 11 and the bit line 12 to cause the selector 15 to transition from the OFF state to the ON state, and applying a predetermined write current through the magnetoresistance effect element 14.

After setting the magnetoresistance effect element 14 to the reference resistance state in the write period, an operation during the second read period is performed.

The basic sequence of the operation during the second read period is similar to the sequence of the operation during the first read period described above.

That is, first, the same voltage Vusel is applied to the word line 11 and the bit line 12. Subsequently, the voltage (Vth+α) is applied to the bit line 12, and further, the bit line 12 is set to the floating state. Subsequently, while the bit line 12 is maintained in the floating state, the voltage of the word line 11 is changed to apply the ground voltage VGND to the word line 11. Accordingly, the voltage (Vth+α) is applied to the memory cell 13, and the selector 15 in the memory cell 13 transitions from the OFF state to the ON state. That is, the selector 15 is set to the ON state at a second ON state setting time point ton2 at which the voltage of the word line 11 is changed to apply the ground voltage VGND to the word line 11 (S14). As a result, the electric potential of the bit line 12 automatically gradually decreases, and when the voltage between the word line 11 and the bit line 12 becomes the hold voltage Vhold, the selector 15 transitions from the ON state to the OFF state.

Similar to the first read period, during the second read period, while the bit line 12 is in the floating state, at a reference voltage obtaining time point tr, which occurs after a second time period elapses since the second ON state setting time point ton2, a voltage applied between the word line 11 and the bit line 12 is obtained as the reference voltage (S15). The reference voltage obtaining time point tr occurs before the selector 15 transitions from the ON state to the OFF state.

When the resistance state to be determined that the magnetoresistance effect element 14 was set to before the first read period is the same as the reference resistance state that the magnetoresistance effect element 14 is set to in the write period, the voltage difference between the voltage to be determined and the reference voltage is small. On the other hand, when the resistance state to be determined is different from the reference resistance state, the voltage difference between the voltage to be determined and the reference voltage is large. Accordingly, the voltage difference between voltage to be determined and the reference voltage is compared with a predetermined voltage difference, and if the voltage difference between the voltage to be determined and the reference voltage is smaller than the predetermined voltage difference, it is determined that the resistance state to be determined is the same as the reference resistance state, and if the voltage difference between the voltage to be determined and the reference voltage is larger than the predetermined voltage difference, it is determined that the resistance state to be determined is different from the reference resistance state.

In this manner, based on the voltage difference between the voltage to be determined and the reference voltage, the resistance state to be determined that the magnetoresistance effect element 14 was set to before the first read period, is determined (S16).

Specifically, in a case where the reference resistance state is the low resistance state, if the voltage difference between the voltage to be determined and the reference voltage is larger than the predetermined voltage difference, it is determined that the resistance state to be determined is the high resistance state, and if the voltage difference between the voltage to be determined and the reference voltage is smaller than the predetermined voltage difference, it is determined that the resistance state to be determined is the low resistance state. In addition, in a case where the reference resistance state is the high resistance state, if the voltage difference between the voltage to be determined and the reference voltage is larger than the predetermined voltage difference, it is determined that the resistance state to be determined is the low resistance state, and if the voltage difference between the voltage to be determined and the reference voltage is smaller than the predetermined voltage difference, it is determined that the resistance state to be determined is the high resistance state.

In the self-reference reading operation described above, due to variation in the characteristics of the memory cell 13, there is a possibility that when the voltage difference between the voltage to be determined and the reference voltage is compared with the predetermined voltage difference, a difference may not be obtained from the comparison because it is too small. In conventional self-reference reading, the first time period and the second time period are the same, and there are cases in which a difference is not obtained. In such cases, it may not be positively determined whether the resistance state to be determined is the low resistance state or the high resistance state.

Therefore, according to embodiments, the determination operation is performed as follows.

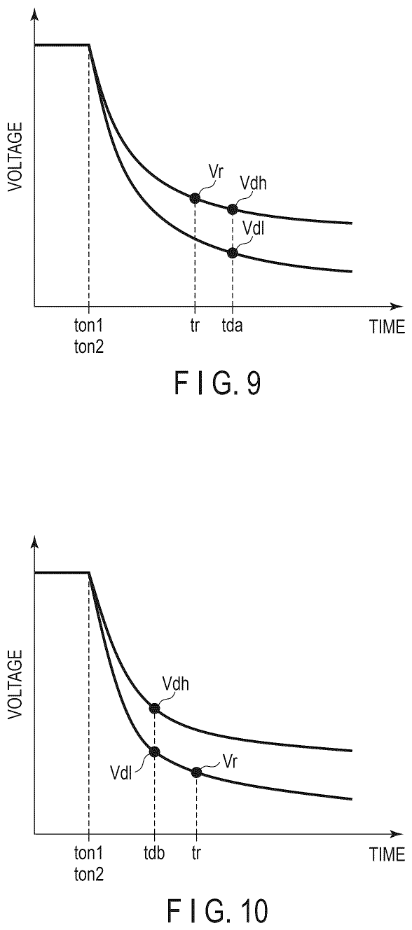

FIG. 9 and FIG. 10 are diagrams illustrating a first example and a second example of the determination operation of embodiments, respectively.

In each of FIG. 9 and FIG. 10, a horizontal axis is the time, and a vertical axis is the electric potential of the bit line 12. Specifically, the electric potential of the bit line 12 during the first read period and the second read period is illustrated. Note that, although the first read period and the second read period are different periods, in FIG. 9 and FIG. 10, in order to make the description easier to understand, the electric potential of the bit line 12 during the first read period and the electric potential of the bit line 12 during the second read period are illustrated on a common time axis. That is, in FIG. 9 and FIG. 10, the first ON state setting time point ton1 at which the selector 15 transitions from the OFF state to the ON state during the first read period, and the second ON state setting time point ton2 at which the selector 15 transitions from the OFF state to the ON state during the second read period are illustrated as coinciding on the horizontal axis.

As illustrated in FIG. 9 and FIG. 10, according to embodiments, the first time period from the first ON state setting time point ton1 to the voltage to be determined obtaining time point td (tda or tdb), and the second time period from the second ON state setting time point ton2 to the reference voltage obtaining time point tr, are set to be different from each other.

In FIG. 9, the reference resistance state is set to the high resistance state, and the first time period and the second time period are set so that the first time period (tda−ton1) becomes longer than the second time period (tr−ton2). Accordingly, when the resistance state to be determined is the low resistance state, the voltage difference between a voltage to be determined Vdl and a reference voltage Vr can be increased, and it is thus possible to accurately determine that the resistance state to be determined is the low resistance state. In addition, when the resistance state to be determined is the high resistance state, since the voltage difference between a voltage to be determined Vdh and the reference voltage Vr is significantly smaller than the voltage difference when the resistance state to be determined is the low resistance state, it is also possible to accurately determine that the resistance state to be determined is the high resistance state based on the voltage difference being relatively small.

In FIG. 10, the reference resistance state is set to the low resistance state, and the first time period and the second time period are set so that the first time period (tdb−ton1) becomes shorter than the second time period (tr−ton2). Accordingly, when the resistance state to be determined is the high resistance state, the voltage difference between the voltage to be determined Vdh and the reference voltage Vr can be increased, and it is possible to accurately determine that the resistance state to be determined is the high resistance state. In addition, when the resistance state to be determined is the low resistance state, since the voltage difference between the voltage to be determined Vdl and the reference voltage Vr is significantly smaller than the voltage difference when the resistance state to be determined is the high resistance state, it is also possible to accurately determine that the resistance state to be determined is the low resistance state based on the voltage difference being relatively small.

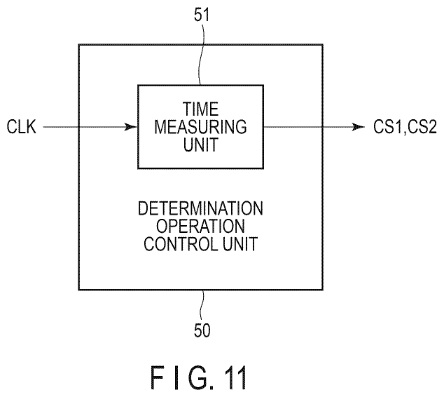

FIG. 11 is a diagram illustrating a time measuring unit 51, also referred to herein as a “timer,” that measures the first time period and the second time period. The time measuring unit 51 is a sub-circuit of the determination operation control unit 50 illustrated in FIG. 1.

The time measuring unit 51 includes a counter for measuring the first time period and the second time period, and the first time period and the second time period are measured by counting a clock signal CLK that is input to the counter. When the first time period elapses during the first read period, a first control signal CS1 is output from the time measuring unit 51, and the voltage to be determined is obtained at the voltage to be determined obtaining time point td based on the first control signal CS1. When the second time period elapses during the second read period, a second control signal CS2 is output from the time measuring unit 51, and the reference voltage is obtained at the reference voltage obtaining time point tr based on the second control signal CS2.

As described above, according to embodiments, the first time period from the first ON state setting time point ton1 to the voltage to be determined obtaining time point td, and the second time period from the second ON state setting time point ton2 to the reference voltage obtaining time point tr are set to be different from each other. Accordingly, the voltage difference between the voltage to be determined (Vdh or Vdl) and the reference voltage Vr can be accurately obtained, and the resistance state to be determined that the magnetoresistance effect element 14 is set to can be accurately determined. Accordingly, in embodiments, it becomes possible to accurately read the data stored in the memory cell 13.

Note that, in the embodiments, although the magnetoresistance effect element 14 is used as the variable resistance memory element, other variable resistance memory elements may be used.

While certain embodiments have been described, these embodiments have been presented by way of example only, and are not intended to limit the scope of the invention. Indeed, the novel devices and methods described herein may be embodied in a variety of other forms; furthermore, various omissions, substitutions and changes in the form of the embodiments described herein may be made without departing from the spirit of the invention. The accompanying claims and their equivalents are intended to cover such forms or modification as would fall within the scope and spirit of the invention.

What is claimed is:

1. A storage device comprising:
a first wire extending in a first direction;
a second wire extending in a second direction that intersects the first direction;
a memory cell connected between the first wire and the second wire, wherein the memory cell includes a variable resistance memory element capable of exhibiting both a first resistance state and a second resistance state having a greater resistance than the first resistance state, and the memory cell further includes a switching element connected in series to the variable resistance memory element, the switching element having characteristics of transitioning from an OFF state to an ON state when a voltage applied between two terminals of the switching element increases to a first voltage, and of transitioning from the ON state to the OFF state when the voltage applied between the two terminals decreases to a second voltage lower than the first voltage; and
a determination operation controller configured to:
change a voltage of the first wire at a first ON state setting time point during a first read period, to set the switching element to the ON state while the second wire is set to a floating state, and obtain a voltage to be determined that is applied between the first wire and the second wire when a first time period elapses since the first ON state setting time point;
set the variable resistance memory element to one of the first resistance state and the second resistance state as a reference resistance state during a write period after the first read period;
change the voltage of the first wire at a second ON state setting time point during a second read period after the write period, to set the switching element to the ON state while the second wire is set to the floating state, and obtain a reference voltage applied between the first wire and the second wire when a second time period, which is different from the first time period, elapses since the second ON state setting time point; and
determine, based on a voltage difference between the voltage to be determined and the reference voltage, a resistance state to be determined that the variable resistance memory element was set to before the first read period.

2. The storage device of claim 1, wherein the determination operation controller is further configured to:
in a case where the reference resistance state is the first resistance state: determine that the resistance state to be determined is the second resistance state if the voltage difference between the voltage to be determined and the reference voltage is larger than a predetermined voltage difference, and determine that the resistance state to be determined is the first resistance state if the voltage difference between the voltage to be determined and the reference voltage is smaller than the predetermined voltage difference.

3. The storage device of claim 1, wherein the determination operation controller is further configured to:
in a case where the reference resistance state is the second resistance state: determine that the resistance state to be determined is the first resistance state if the voltage difference between the voltage to be determined and the reference voltage is larger than a predetermined voltage difference, and determine that the resistance state to be determined is the second resistance state if the voltage difference between the voltage to be determined and the reference voltage is smaller than the predetermined voltage difference.

4. The storage device of claim 1, wherein in a case where the reference resistance state is the first resistance state, the first time period and the second time period are set so that the first time period is shorter than the second time period.

5. The storage device of claim 1, wherein in a case where the reference resistance state is the second resistance state, the first time period and the second time period are set so that the first time period is longer than the second time period.

6. The storage device of claim 1, wherein
a resistance of the switching element in the OFF state is higher than the resistance of the variable resistance memory element in the second resistance state, and
the resistance of the switching element in the ON state is lower than the resistance of the variable resistance memory element in the first resistance state.

7. The storage device of claim 1, wherein the determination operation controller includes a timer that measures the first time period and the second time period.

8. The storage device of claim 1, wherein the variable resistance memory element is a magnetoresistance effect element.

9. The storage device of claim 8, wherein the magnetoresistance effect element includes a first magnetic layer with a variable magnetization direction, a second magnetic layer with a fixed magnetization direction, and a non-magnetic layer provided between the first magnetic layer and the second magnetic layer.

10. The storage device of claim 9, wherein the magnetoresistance effect element exhibits the first resistance state when the magnetization direction of the first magnetic layer is parallel to the magnetization direction of the second magnetic layer, and exhibits the second resistance state when the magnetization direction of the first magnetic layer is antiparallel to the magnetization direction of the second magnetic layer.

11. The storage device of claim 1, wherein the switching element includes a switching material layer formed of silicon oxide containing a predetermined element.

12. A method of performing self-reference reading using a storage device, wherein the storage device comprises a first wire extending in a first direction, a second wire extending in a second direction that intersects the first direction, and a memory cell connected between the first wire and the second wire, the memory cell including a variable resistance memory element and a switching element connected in series to the variable resistance memory element, the method comprising:
changing a voltage of the first wire at a first ON state setting time point during a first read period, to set the switching element to an ON state while the second wire is set to a floating state, and obtaining a voltage to be determined that is applied between the first wire and the second wire when a first time period elapses since the first ON state setting time point;
setting the variable resistance memory element to one of a first resistance state and a second resistance state having a greater resistance than the first resistance state, as a reference resistance state during a write period after the first read period;
changing the voltage of the first wire at a second ON state setting time point during a second read period after the write period, to set the switching element to the ON state while the second wire is set to the floating state, and obtaining a reference voltage applied between the first wire and the second wire when a second time period, which is different from the first time period, elapses since the second ON state setting time point; and
determining, based on a voltage difference between the voltage to be determined and the reference voltage, a resistance state to be determined that the variable resistance memory element was set to before the first read period.

13. The method of claim 12, further comprising:
in a case where the reference resistance state is the first resistance state: determining that the resistance state to be determined is the second resistance state if the voltage difference between the voltage to be determined and the reference voltage is larger than a predetermined voltage difference, and determining that the resistance state to be determined is the first resistance state if the voltage difference between the voltage to be determined and the reference voltage is smaller than the predetermined voltage difference.

14. The method of claim 12, further comprising:
in a case where the reference resistance state is the second resistance state: determining that the resistance state to be determined is the first resistance state if the voltage difference between the voltage to be determined and the reference voltage is larger than a predetermined voltage difference, and determining that the resistance state to be determined is the second resistance state if the voltage difference between the voltage to be determined and the reference voltage is smaller than the predetermined voltage difference.

15. The method of claim 12, further comprising:
in a case where the reference resistance state is the first resistance state, setting the first time period and the second time period so that the first time period is shorter than the second time period.

16. The method of claim 12, further comprising:
in a case where the reference resistance state is the second resistance state, setting the first time period and the second time period so that the first time period is longer than the second time period.

17. The method of claim 12, wherein
a resistance of the switching element in an OFF state is higher than the resistance of the variable resistance memory element in the second resistance state, and
the resistance of the switching element in the ON state is lower than the resistance of the variable resistance memory element in the first resistance state.

18. The method of claim 12, wherein the determination operation controller includes a timer that measures the first time period and the second time period.

19. The method of claim 12, wherein the variable resistance memory element is a magnetoresistance effect element.

20. The method of claim 19, wherein the magnetoresistance effect element includes a first magnetic layer with a variable magnetization direction, a second magnetic layer with a fixed magnetization direction, and a non-magnetic layer provided between the first magnetic layer and the second magnetic layer.
